(19) United States
(12) Patent Application Publication
(10) Pub. No.: US 2007/0096233 A1
(43) Pub. Date: May 3, 2007

(54) CMOS IMAGE SENSOR

(76) Inventor: In Gyun Jeon, Gyeonggi-do (KR)

Correspondence Address: SHERR & NOURSE, PLLC, 620 HERNDON PARKWAY, SUITE 200, HERNDON, VA, 20170, US

(21) Appl. No.: 11/548,496

(22) Filed: Oct. 11, 2006

(30) Foreign Application Priority Data
Oct. 13, 2005 (KR) 10-2005-0096364

(51) Int. Cl. H01L 27/14

(52) U.S. Cl. 257/431

(57) ABSTRACT

A CMOS image sensor includes a semiconductor substrate with an active area. A photodiode and a plurality of transistors may be formed on the active area. The active area has a portion with a variable width below a reset transistor.

The present application claims priority under 35 U.S.C. 119 and 35 U.S.C. 365 to Korean Patent Application No. 10-2005-0096364 (filed on Oct. 13, 2005), which is hereby incorporated by reference in its entirety.

### BACKGROUND

1. Field of the Invention

Embodiments relate to a CMOS image sensor having an active area at a lower portion of a transistor.

2. Description of the Prior Art

In general, complementary metal-oxide semiconductor (CMOS) image sensors may employ a switching mode to sequentially detect an output of each unit pixel using MOS transistors. MOS transistors may be formed on a semiconductor substrate, with each set of transistors corresponding to each unit pixel. CMOS technology may use peripheral devices (such as controllers and signal processors) during operation.

The CMOS image sensors may be classified into 3T, 4T and 5T-type CMOS image sensors, in accordance with the number of transistors. A 3T-type CMOS image sensor may include one photodiode and three transistors. A 4T-type CMOS image sensor may include one photodiode and four transistors.

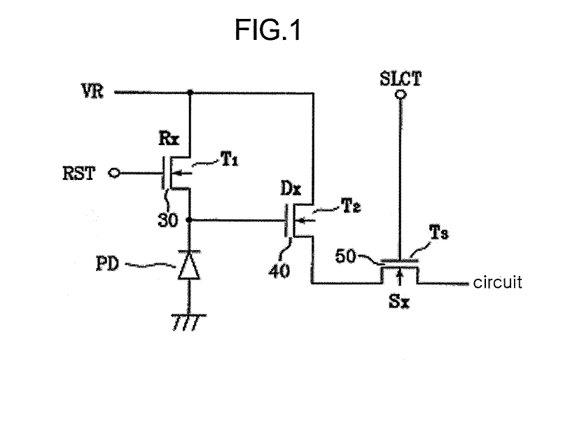

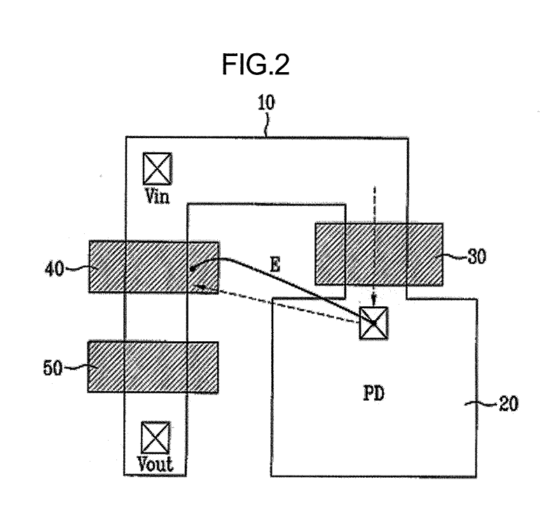

Example FIG. 1 is a circuit diagram of a 3T-type CMOS image sensor. Example FIG. 2 is a layout view illustrating a 3-T type CMOS image sensor. As illustrated in FIG. 1, a 3T-type CMOS image sensor may includes one photodiode (PD) and three n-channel metal-oxide semiconductor (nMOS) transistors T1, T2, and T3.

A cathode of photodiode PD may be connected to a drain of first nMOS transistor T1 and a gate of second NMOS transistor T2. Both sources of first and second NMOS transistors T1 and T2 are connected to a power line which may supply reference voltage VR. A gate of first nMOS transistor T1 may be connected to a reset line which may supply reset signal RST. A source of third nMOS transistor T3 may be connected to a drain of second nMOS transistor T2. A drain of third nMOS transistor T3 may be connected to a readout circuit through a signal line. A gate of third nMOS transistor T3 may be connected to a column select line which may provide a selection signal SLCT. In accordance with the operation of nMOS transistors, first, second, and third nMOS transistors T1, T2, and T3 may be called reset, drive, and select transistors 30, 40, and 50, respectively.

As illustrated in example FIG. 2, active area 10 may include devices, such as transistors. Transistors may be formed on a semiconductor substrate. PD 20 may be formed at one side of active area 10. Gate electrodes of three transistors 30, 40, and 50 may overlap active area 10. A source/drain area of each transistor may be formed in active area.

Voltage input terminal Vin may be connected to a source/drain between reset transistor 30 and the drive transistor 40. Voltage output terminal Vout may be connected to a source/drain area of select transistor 50. Each gate electrode may be connected to each signal line and each signal line may have a pad to connect to an external driving circuit. A gate electrode of drive transistor 40 may be electrically connected to PD 20 through conductive line E. Reset transistor 30 may apply the potential of external input voltage terminal Vin to PD 20. Reset transistor 30 may deliver the potential generated from PD 20 to drive transistor 40.

Reset transistor 30 may have a one-way operational direction (e.g. see the arrow in FIG. 2). Accordingly, external potential may be applied to PD 20 through reset transistor 30. Potential variation of PD 20 may be transferred to drive transistor 40 through metal line E. Reset transistor 30 may deliver the potential of input voltage terminal Vin to PD 20 when the reset transistor is turned on and block the potential of PD 20 when reset transistor 30 is turned off.

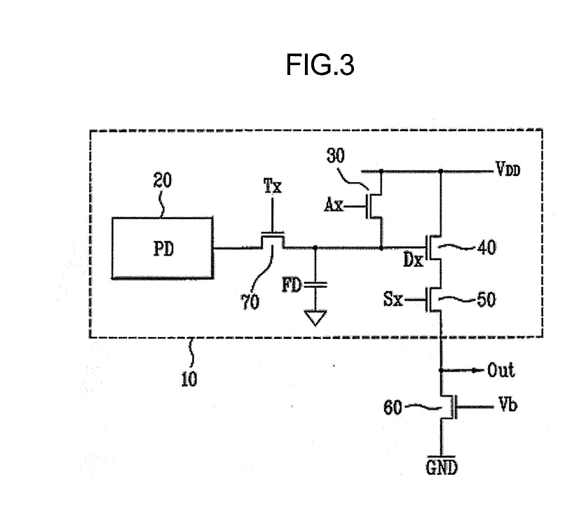

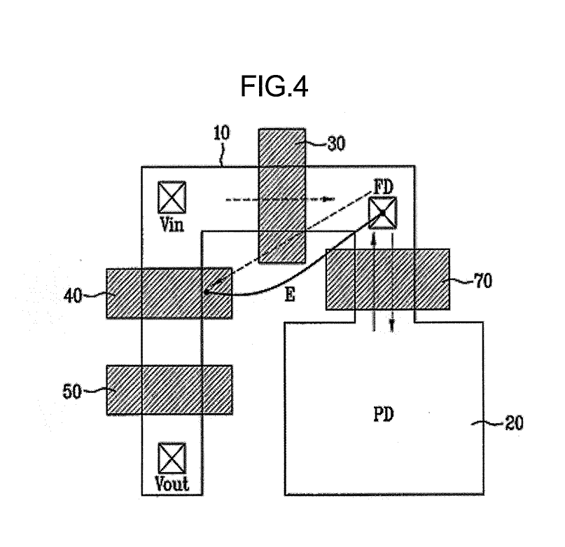

Example FIG. 3 is an equivalent circuit diagram of a 4T-type CMOS image sensor. Example FIG. 4 is a layout view illustrating a 4-T type CMOS image sensor. As illustrated in FIGS. 3 and 4, a unit pixel may include PD 20 and four MOS transistors. An active area 10 may represent a unit pixel, in which PD 20 is formed at one side of active area 10. PD 20 may generate optical charges by receiving light. Transfer transistor 70 may carry optical charges collected in PD 20 to floating diffusion (FD) area.

A 4T-type CMOS image sensor may include reset transistor 30 which may reset FD by regulating the voltage at FD to a desired level and discharging electrons. Drive transistor 40 may serve as a source follow buffer amplifier. Select transistor 50 may perform switching and/or addressing functions. Load transistor 60 may be formed at the outside of a pixel unit and may read an output signal. Voltage Tx represents a gate voltage of transfer transistor 70. Voltage Dx represents a gate voltage of drive transistor 40. Voltage Sx represents a gate voltage of select transistor 50. Reset transistor 30 of a 4T-type CMOS image sensor may have a similar structure and function as reset transistor 30 of a 3T-type CMOS image sensor. Transfer transistor 70 may operate bi-directionally as illustrated by the arrows in FIG. 4 through transfer transistor 70. Reset transistor 30 may have a one-way operational direction as illustrated by the arrow in FIG. 4 through reset transistor 30.

In CMOS image sensors illustrated in FIGS. 1-4, an active area of a reset transistor is formed with a rectangle shape. A rectangular shaped active area of a reset transistor makes it difficult to effectively block the potential of a PD when the reset transistor is turned off. Additionally, the potential of a PD may not be effectively transferred to a drive transistor, but may leak when a reset transistor is turned off. Accordingly, operational performance of a CMOS image sensor may be degraded by a rectangular shaped active area of a reset transistor.

### SUMMARY

Embodiments relate to a CMOS image sensor that may substantially prevent potential leakage from a photodiode to a reset transistor. In embodiments a CMOS image sensor may include a semiconductor substrate having an active area, a photodiode formed on one side of the active area, and a plurality of transistors formed on the active area. In embodiments, an active area of a semiconductor substrate is formed with at least one portion having a variable width.

### BRIEF DESCRIPTION OF THE DRAWINGS

Example FIG. 1 is an equivalent circuit diagram illustrating a 3 T-type CMOS image sensor.

Example FIG. 2 is a layout view illustrating a 3 T-type CMOS image sensor.

Example FIG. 3 is an equivalent circuit diagram illustrating a 4 T-type CMOS image sensor.

Example FIG. 4 is a layout view illustrating a 4T-type CMOS image sensor.

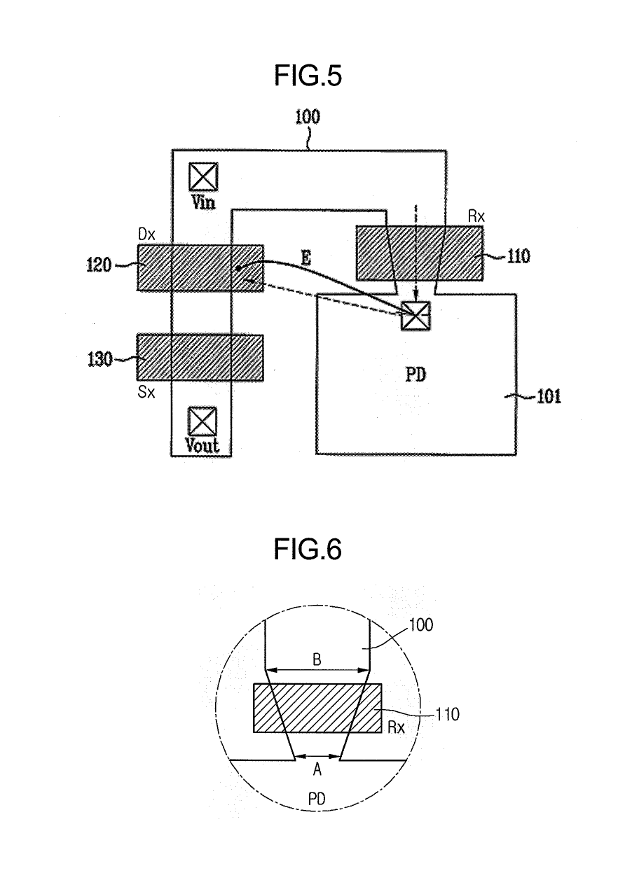

Example FIG. 5 is a layout view illustrating a pixel of a CMOS image sensor, in accordance with embodiments.

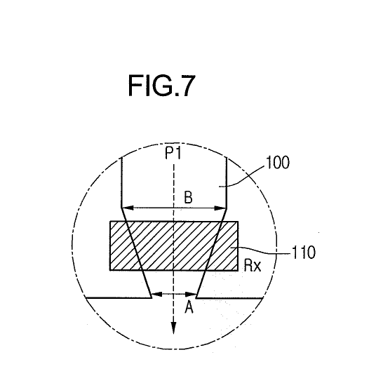

Example FIGS. 6 and 7 are enlarged views illustrating an active area, in accordance with embodiments.

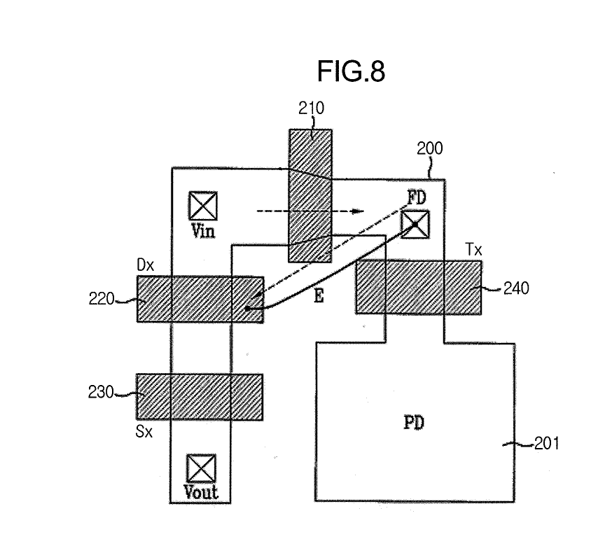

Example FIG. 8 is a layout view illustrating a pixel of a CMOS image sensor, in accordance with embodiments.

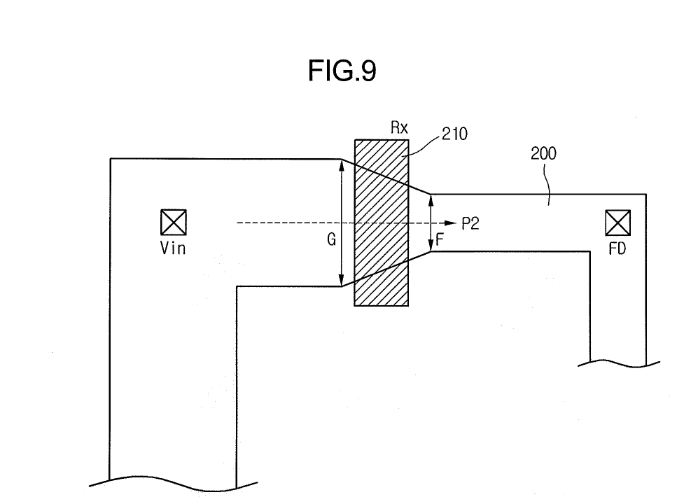

Example FIG. 9 is an enlarged view illustrating an active area, in accordance with embodiments.

### DETAILED DESCRIPTION

Technical features of a CMOS image sensor may adaptable for 3T, 4T, and 5T-type CMOS image sensors, in accordance with embodiments. Example 3T and 4T-type CMOS image sensors, in accordance of embodiments, are illustrated in example FIGS. 5-9.

Example FIG. 5 is a layout view illustrating a pixel of a CMOS image sensor, according to embodiments. Example FIGS. 6 and 7 are enlarged views illustrating active area 100, according to embodiments.

As illustrated in FIG. 5, a CMOS image sensor may include active area 100, according to embodiments. Photodiode (PD) 101 may be formed at one side of active area 100. Gate electrodes 110, 120, and 130 of three transistors may overlap active area 100. It is well known to those skilled in the art that active area 100 can be formed in a semiconductor substrate through a shallow trench isolation (STI) process.

A CMOS image sensor may include reset transistor Rx with first gate electrode 110, drive transistor Dx with second gate electrode 120, and/or select transistor Sx with third gate electrode 130.

In embodiments, lower portions of first gate electrode 110, second gate electrode 120, and third gate electrode 130 may be formed to overlap active area 100. Active area 100 may be implanted with P type dopants. Source/drain areas of reset transistor Rx, drive transistor Dx, and select transistor Sx may be formed in active area 100. In embodiments, source/drain areas of reset transistor Rx, drive transistor Dx, and select transistor Sx may overlap active area 100.

Voltage input voltage Vin may be applied between drive transistor Dx and reset transistor Rx. Voltage output terminal Vout may be connected to a source/drain area on one side of select transistor Sx. Reset transistor Rx may control the potential of a floating diffusion layer and may perform a reset function. Drive transistor Dx may serve as a source follower. Select transistor Sx may perform a switching function such that a signal from a pixel unit may be read.

In embodiments, line E (illustrated in FIG. 5) may be a conductive metal line which may electrically connect PD 101 to drive transistor Dx.

Since the width of active area 100 at the lower part of reset transistor Rx may vary, potential may be shifted to PD 101 from voltage input terminal Vin when reset transistor Rx is turned on and potential may be moved from PD 101 to drive transistor Dx when reset transistor Rx is turned off.

The width of a portion of active area 100 which overlaps with reset transistor Rx may be gradually narrowed towards the direction of PD 101. A predetermined portion of active area 100 that is positioned at a lower portion of first gate electrode 110 of reset transistor Rx may gradually narrow. The width of the portion of active area 100 which overlaps with reset transistor Rx may gradually narrow. For example, active area 100 may include a first area having a width B and a second area having a width A. Width A may be smaller than width B. Reset transistor Rx may overlap both a first area having a width B and a second area having a width A.

Active area 100 may have a section with a variable width. Width A of an area adjacent to PD 101 may be smaller than width B of an area adjacent to voltage input terminal Vin. An area of active area 100 which overlap reset transistor Rx has a width that gradually narrows in the direction of PD 101.

As illustrated in FIG. 7, functions of active area 100 may be illustrated by the direction of movement of potential generated from voltage input terminal Vin, in accordance with embodiments. When reset transistor 110 is turned on, potential generated from voltage input terminal Vin may move direction P1 (illustrated in FIG. 7) to PD 101. Active area 100 may include a section having a shrinking width in the direction of the potential from voltage input terminal Vin to PD 101 through reset transistor 110. Accordingly, in embodiments, potential from input terminal Vin may be supplied to PD 101 without significant return of potential from PD 101 back to through reset transistor Rx. Accordingly, potential shifted into PD 101 may be effectively and efficiently transferred to drive transistor Dx. In embodiments, a bottle neck phenomenon occurs.

Example FIG. 8 is a layout view illustrating a pixel of a CMOS image sensor, in accordance with embodiments. Example FIG. 9 is an enlarged view illustrating active area 200, in accordance with embodiments. As illustrated in FIG. 8, a CMOS image sensor may include active area 200. Photodiode (PD) 202 may be formed at one side of active area 200. Gate electrode 210, gate electrode 220, gate electrode 230, and gate electrode 240 of four transistors may overlap active area 200.

CMOS image sensor may include reset transistor Rx having first gate electrode 210, drive transistor Dx having second gate electrode 220, select transistor Sx having third gate electrode 230, and/or transfer transistor Tx having fourth gate electrode 240. At lower portions of gate electrode 210, gate electrode 220, gate electrode 230, and gate electrode 240, a P type impurity area may be formed in the area that overlaps active area 200. Source and drain areas may be formed in active area 200 next to lower parts of gate electrode 210, gate electrode 220, gate electrode 230, and gate electrode 240 by implanting dopants.

Voltage input terminal Vin may be formed between drive transistor Dx and reset transistor Rx. Voltage output terminal Vout may be connected to a source/drain area on a side of select transistor Sx.

Transfer transistor Tx may carry optical charges generated from PD 201 to floating diffusion area FD. In embodiments, other transistors illustrated in FIG. 8 may have similar operations and functions as transistors illustrated in FIG. 5. For example, active area 200 may overlap with gate electrode 210 of reset transistor Rx. Gate electrode 210 may include a section that overlaps with active area 200 having a variable width. Gate electrode 210 may be formed in active area 200 between voltage input terminal Vin and floating diffusion area FD.

Example FIG. 9 illustrates active area 200, according to embodiments. Active area 200 may be formed with voltage input terminal Vin and floating diffusion area FD. Potential from voltage input terminal Vin may be transferred to PD 201 when reset transistor Rx is turned on. Floating diffusion area FD is formed in an active area between voltage input terminal Vin and PD 201.

A section of active area 200 is formed between voltage input terminal Vin and PD 201 with a varying width. The width of active area 200 that overlaps reset transistor Rx may vary. Active area 200 may include a first portion having width F and a second portion having width G. Width F may be smaller than width G. A first portion having width F may be closer to PD 201 than a second portion having width G. Active area 200, which may connect a power supply voltage from voltage input terminal Vin to floating diffusion area FD area, may be formed to have a variable from width G to width F. Width F may be smaller than the width G.

In embodiments, potential generated from voltage terminal Vin moves in the direction P2 (illustrated in FIG. 9) to PD 201 through floating diffusion area FD. Active area 200 may have a section with a gradually reducing width that gradually reduces in the direction of electrical potential that flows when reset transistor Rx is turned on. In embodiments, potential can be supplied to PD 201 when reset transistor Rx is turned on and may reduce movement of potential from PD 201 to voltage terminal Vin when reset transistor Rx is turned off. In embodiments, potential can easily move from PD 201 to drive transistor Dx.

It will be apparent to those skilled in the art that various modifications and variations can be made to embodiments. Thus, it is intended that embodiments cover modifications and variations thereof within the scope of the appended claims.

What is claimed is:

1. An apparatus comprising:
a semiconductor substrate comprising an active area;
a photodiode formed on the active area; and
at least one transistor formed on the active area, wherein a portion of the active area has a variable width.

2. The apparatus of claim 1, wherein the apparatus is a CMOS image sensor.

3. The apparatus of claim 1, wherein the photodiode is formed at one side of the active area.

4. The apparatus of claim 1, wherein:
said at least one transistor comprises a reset transistor;
the reset transistor is configured to perform a reset function; and
the portion of the active area that has a variable with is part of the reset transistor.

5. The apparatus of claim 4, wherein the width of the portion of the active area that has a variable width varies in a direction that potential moves to the photodiode when the reset transistor is turned on.

6. The apparatus of claim 5, wherein the potential is supplied by a voltage input terminal.

7. The apparatus of claim 1, wherein the width of the portion of the active area that has a variable width becomes more narrow closer to the photodiode.

8. The apparatus of claim 1, wherein the active area is below at least one gate electrode of said at least one transistor.

9. The apparatus of claim 1, wherein the active area is implanted with P type dopants.

10. The apparatus of claim 1, wherein said at least one transistor comprises at least one of:
a reset transistor configured to control potential of a floating diffusion layer;
a drive transistor configured as a source follower; and
a select transistor configured to perform a switching function to read a signal from a pixel.

11. An apparatus comprising:
an active area which overlaps at least one transistor, wherein a section of the active area is below at least one transistor and the section of the active area below at least one transistor has a variable width; and
a photodiode formed on the active area configured to generate optical charges.

12. The apparatus of claim 11, wherein the apparatus is a CMOS image sensor.

13. The apparatus of claim 11, wherein the photodiode is formed at one side of the active area.

14. The apparatus of claim 11, wherein said at least one transistor comprises a reset transistor configured to move external potential to the photodiode.

15. The CMOS image sensor as claimed in claim 11, wherein the width of the active area formed in the lower side of the reset transistor is gradually narrowed in a direction of the photodiode.

16. The apparatus of claim 11, wherein the width of the active area below said at least one transistor narrows in a direction that potential moves to the photodiode.

17. The apparatus of claim 11, comprising a transfer transistor, wherein:
the transfer transistor is configured to carry optical charges to a floating diffusion area;
the transfer transistor is between the reset transistor and the photodiode; and
the section of the active area below at least one transistor has a width that is greater at a position closer to the reset transistor than a position closer to the transfer transistor.

18. The apparatus of claim 11, comprising:
a voltage input terminal on the active area, wherein the voltage input terminal is configured to feed external potential; and
a transfer transistor configured to carry optical charges, wherein the section of the active below said at least one transistor has a variable width between the voltage input terminal and the transfer transistor.

19. The apparatus of claim 18, wherein the width of the portion of the active area that has a variable width becomes more narrow closer to the transfer transistor.
